(19) United States
(12) Patent Application Publication
(10) Pub. No.: US 2026/0068058 A1
(43) Pub. Date: Mar. 5, 2026

(54) TAPE AND MANUFACTURING METHOD THEREOF

(71) Applicant: CHIPBOND TECHNOLOGY CORPORATION, Hsinchu (TW)

(72) Inventors: Yi-Hui Chen, Hsinchu City (TW); Yi-Hua Huang, Hsinchu City (TW); Yen-Ping Huang, Hsinchu City (TW); Shih-Chieh Chang, Chiayi County (TW)

(21) Appl. No.: 19/385,335

(22) Filed: Nov. 11, 2025

Related U.S. Application Data
(62) Division of application No. 18/109,334, filed on Feb. 14, 2023.

(30) Foreign Application Priority Data
May 18, 2022 (TW) 111118594

(51) Int. Cl. H05K 3/04

(52) U.S. Cl. CPC H05K 3/041; H05K 2203/0143; H05K 2203/0191; H05K 2203/0228; H05K 2203/0278

(57) ABSTRACT

A manufacturing method of tape includes the steps of providing a tape including substrate units, providing a die device and a cutting and/or pressing process. Each of the substrate units includes a carrier, a circuit layer, an adhesive and a heat spreader, the heat spreader is attached onto the carrier by the adhesive. In the cutting and/or pressing process, the die device is provided to press the tape to generate separation protrusions on the heat spreader and allow the separation protrusions to protrude from a heat dissipation surface of the heat spreader. When rolling the tape, the separation protrusions can separate the stacked substrate units to prevent the adhesive from being squeezed out to contaminate the tape.

### CROSS-REFERENCE TO RELATED APPLICATIONS

This application is a divisional application of U.S. patent application Ser. No. 18/109,334, filed on Feb. 14, 2023, which claims priority under 35 U.S.C. § 119(a) to Patent Application No. 111118594, filed in Taiwan, Republic of China on May 18, 2022, the entire contents of which are hereby incorporated by reference.

### FIELD OF THE INVENTION

This invention relates to a tape and its manufacturing method, and more particularly to a tape able to prevent adhesive contamination and its manufacturing method.

### BACKGROUND OF THE INVENTION

Conventionally printed circuit board tape is rolled and transported to stations for chip bonding, testing and other processes, and a protection tape is provided to protect the printed circuit board tape during rolling. A stress is applied to the printed circuit board tape and the protection tape during rolling, however, the stress may squeeze an adhesive used to adhere a heat spreader onto the printed circuit board tape out of the heat spreader and cause contamination on the printed circuit board tape and the protection tape. Furthermore, another printed circuit board may be contaminated while the protection tape adhered with the adhesive is reused.

### SUMMARY OF THE INVENTION

One object of the present invention is to provide a manufacturing method of a tape which is able to prevent contamination of an adhesive used to adhere a heat spreader onto a carrier.

A manufacturing method of a tape includes the following steps: providing a tape including a plurality of substrate units, providing a die device including a plurality of punch-pressing elements, and performing a cutting and/or pressing process. Each of the substrate units includes a carrier, a circuit layer, an adhesive and a heat spreader, the circuit layer is located on the carrier, the heat spreader is attached onto the carrier by the adhesive. In the cutting and/or pressing process, the punch-pressing elements of the die device are provided to press the tape to generate a plurality of separation protrusions on the heat spreader. The separation protrusions protrude from a heat dissipation surface of the heat spreader.

A tape of the present invention includes a plurality of substrate units. Each of the substrate units includes a carrier, a circuit layer, an adhesive and a heat spreader, the circuit layer is located on the carrier, the heat spreader is attached onto the carrier by the adhesive and includes a plurality of separation protrusions which protrude from a heat dissipation surface of the heat spreader.

In the present invention, the separation protrusions are formed on the heat spreader in the cutting and/or pressing process. While rolling the tape with a protection tape, the separation protrusions are provided to separate the stacked tapes so as to prevent the adhesive from being moved out to contaminate the tape and the protection tape.

### BRIEF DESCRIPTION OF DRAWINGS

FIG. 1 is a top view diagram illustrating a tape in accordance with one embodiment of the present invention.

FIG. 2 is a bottom view diagram illustrating a tape in accordance with one embodiment of the present invention.

FIG. 3 is a cross-section view diagram illustrating a chip-mounted unit of a tape in accordance with one embodiment of the present invention.

FIG. 4 is a cross-section view diagram illustrating a die device and a chip-mounted unit of a tape in accordance with one embodiment of the present invention.

FIG. 5 is a bottom view diagram illustrating a tape in accordance with one embodiment of the present invention.

FIG. 6 is a cross-section view diagram illustrating a tape in accordance with one embodiment of the present invention.

FIG. 7 is a cross-section view diagram illustrating a tape in accordance with one embodiment of the present invention.

FIG. 8 is a cross-section view diagram illustrating a tape in accordance with one embodiment of the present invention.

### DETAILED DESCRIPTION OF THE INVENTION

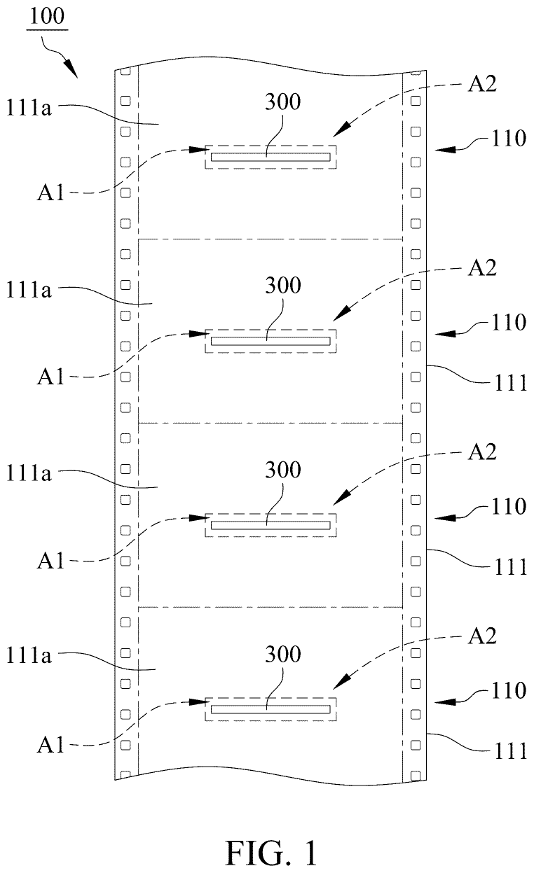

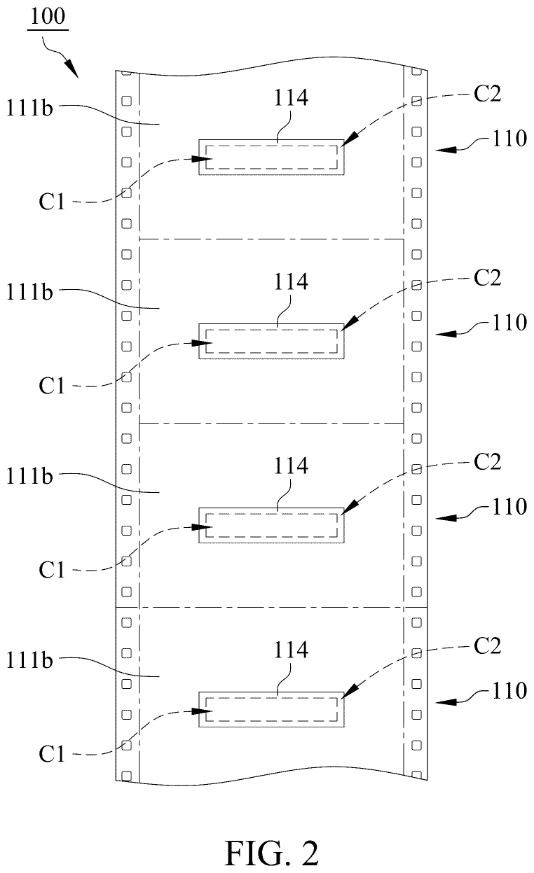

With reference to FIGS. 1 to 3, a manufacturing method of a tape in accordance with one embodiment of the present invention includes the steps of providing a tape 100, providing a die device 200 and a cutting and/or pressing process. The tape 100 includes a plurality of substrate units 110, and in this embodiment, electronic components, such as chips, can be mounted on the substrate units 110 respectively. Each of the substrate units 110 includes a carrier 111, a circuit layer 112, an adhesive 113 and a heat spreader 114. The circuit layer 112 is located on a top surface 111a of the carrier 111 and includes a plurality of inner leads 112a. The heat spreader 114 is adhered on a bottom surface 111b of the carrier 111 by the adhesive 113, and it has a heat dissipation surface 114a which is exposed. In this embodiment, a chip-mounted unit 400 can be obtained after bonding a chip 300 to the inner leads 112a of each of the substrate units 110. Preferably, a underfill material (not shown) can be provided between the chip 300 and the inner leads 112a.

With reference to FIGS. 1 to 3, in this embodiment, the carrier 111 includes a to-be-removed portion A1 where the inner leads 112a are located on, the adhesive 113 includes a first to-be-removed portion B1 corresponding to and located below the to-be-removed portion A1 of the carrier 111, and the heat spreader 114 includes a second to-be-removed portion C1 corresponding to and located below the to-be-removed portion A1 of the carrier 111. If the chip-mounted unit 400 or the substrate unit 110 is referred to as a defective product, the to-be-removed portion A1, the first to-be-removed portion B1 and the second to-be-removed portion C1 will be removed in the cutting and/or pressing process. On the other hand, the to-be-removed portion A1, the first to-be-removed portion B 1 and the second to-be-removed portion C1 will not be removed in the cutting and/or pressing process and will be rolled with the tape 100 for the next process when the chip-mounted unit 400 or the substrate unit 110 is referred to as a non-defective product.

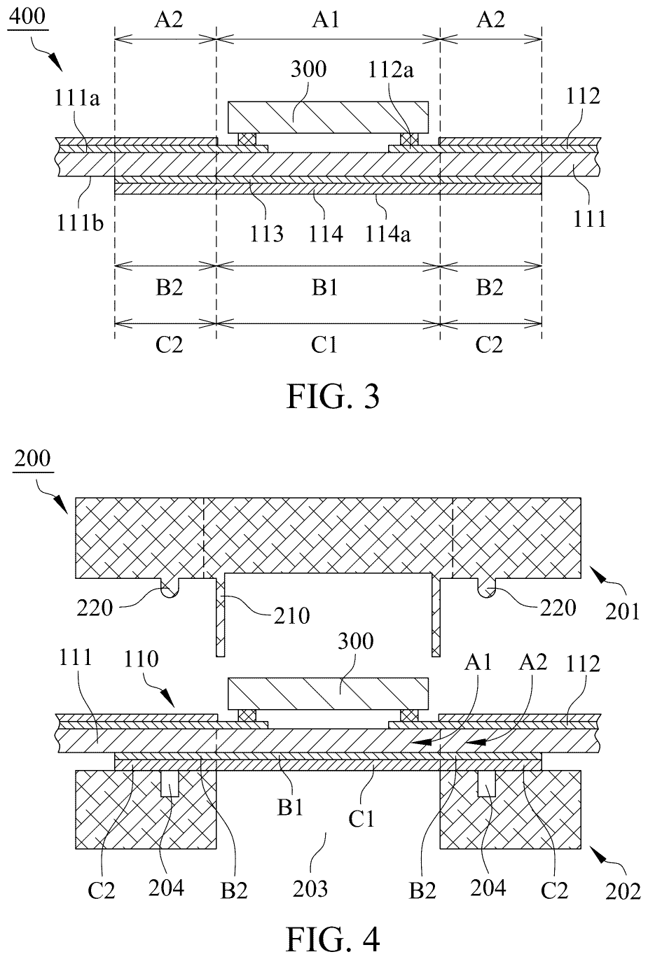

With reference to FIGS. 3 and 4, the die device 200 includes a plurality of punch-pressing elements 220, and preferably, the die device 200 further includes a punch-cutting element 210, the punch-pressing elements 220 are located outside the punch-cutting element 210. In this embodiment, the punch-cutting element 210 and the punch-pressing elements 220 are arranged on an upper die 201 of the die device 200, and a die opening 203 corresponding to the punch-cutting element 210 and die cavities 204 corresponding to the punch-pressing elements 220 are arranged on a lower die 202 of the die device 200. The punch-cutting element 210 and the punch-pressing elements 220 can be moved together or moved individually, and the present invention does not limit the operation and formation of the die device 200.

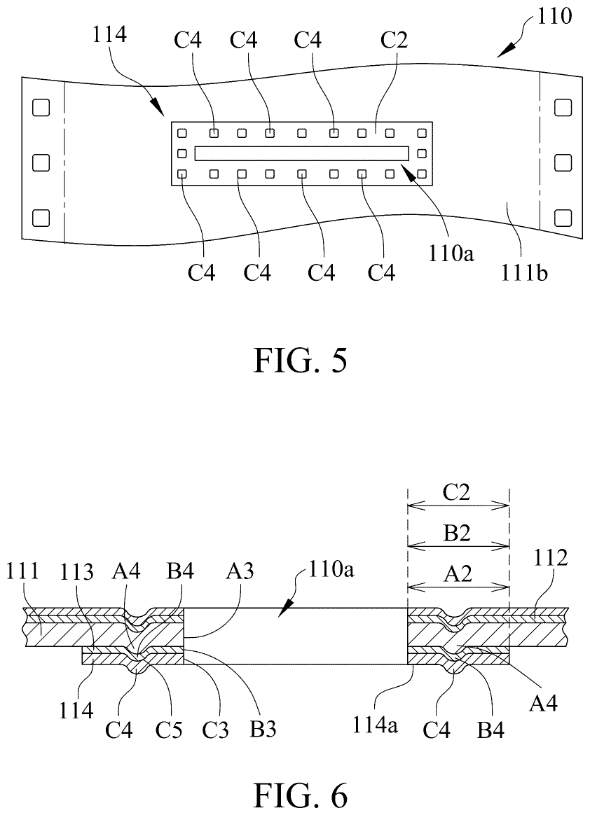

With reference to FIGS. 3 to 6, the punch-cutting element 210 is provided to cut the to-be-removed portion A1 of the carrier 111, the first to-be-removed portion B1 of the adhesive 113 and the second to-be-removed portion C1 of the heat spreader 114 in the cutting and/or pressing process while the chip-mounted unit 400 or the substrate unit 110 is referred to as a defective product. Thus, the to-be-removed portion A1 is separated from the carrier 111, the first to-be-removed portion B1 is separated from the adhesive 113, and the second to-be-removed portion C1 is separated from the heat spreader 114. The chip 300 and the inner leads 112a of the circuit layer 112 are also removed together with the to-be-removed portion A1 by the punch-cutting element 210. After the cutting and/or pressing process, there are a reserve portion A2 and an opening A3 on the cut carrier 111, a first reserve portion B2 and a first opening B3 on the cut adhesive 113, and a second reserve portion C2 and a second opening C3 on the cut heat spreader 114. The reserve portion A2 is located outside the opening A3, the first reserve portion B2 is located outside the first opening B3, and the second reserve portion C3 is located outside the second opening C3. The opening A3, the first opening B3 and the second opening C3 are referred as a hollow portion 110a of the substrate unit 110. In the cutting and/or pressing process, the punch-pressing elements 220 are provided to press the reserve portion A2 of the carrier 111, the first reserve portion B2 of the adhesive 113 and the second reserve portion C2 of the heat spreader 114 to generate a plurality of separation protrusions C4 on the second reserve portion C2 of the heat spreader 114. The separation protrusions C4 are located outside the second opening C3 and protrude from the heat dissipation surface 114a of the heat spreader 114.

With reference to FIGS. 4 to 6, in this embodiment, a plurality of first restriction protrusions B4 are formed on the first reserve portion B2 of the adhesive 113 after the reserve portion A2 of the carrier 111 is pressed by the punch-pressing elements 220, and each of the first restriction protrusions B4 is located within a restriction recess C5 of each of the separation protrusions C4. The first restriction protrusions B4 located within the restriction recesses C5 can hold the first reserve portion B2 of the adhesive 113 as the first to-be-removed portion B1 of the adhesive 113 is removed by the punch-cutting element 210, thus the first reserve portion B2 of the adhesive 113 will not be pulled and moved to the hollow portion 110a by the punch-cutting element 210.

With reference to FIGS. 4 to 6, preferably, a plurality of restriction protrusions A4 are formed on the reserve portion A2 of the carrier 111 after the reserve portion A2 is pressed by the punch-pressing elements 220. The restriction protrusions A4 are inserted into the first reserve portion B2 of the adhesive 113 such that the first restriction protrusions B4 of the adhesive 113 are clamped between the restriction protrusions A4 of the carrier 111 and the separation protrusions C4 of the heat spreader 114. The clamping force applied on the first reserve portion B2 of the adhesive 113 by the reserve portion A2 of the carrier 111 and the second reserve portion C2 of the heat spreader 114 can prevent the first reserve portion B2 of the adhesive 113 from being pulled by the punch-cutting element 210 and moved to the hollow portion 110a of the substrate unit 110.

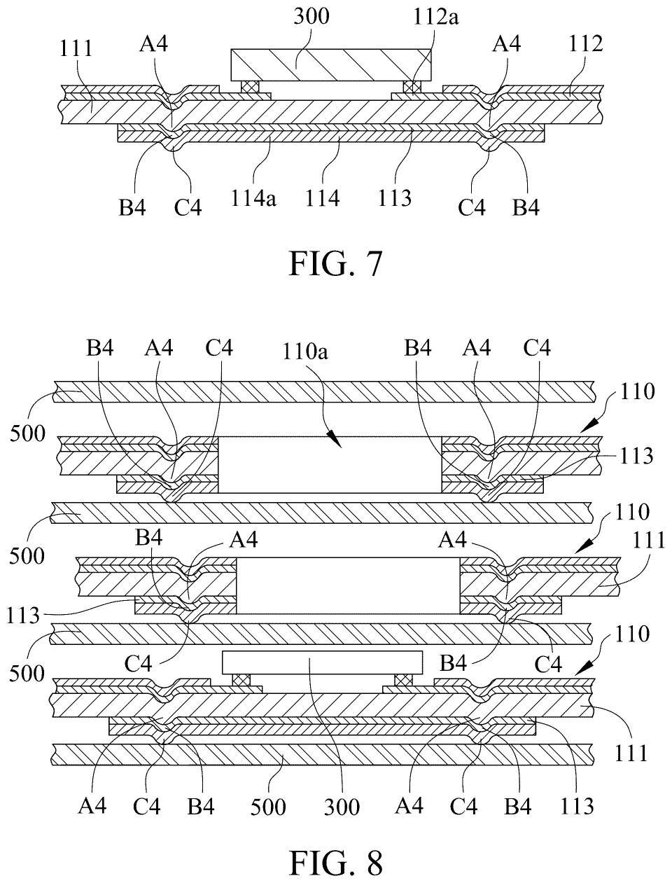

With reference to FIGS. 4 and 7, when the chip-mounted unit 400 or the substrate unit 110 is recognized as an acceptable product, the chip 300, the inner leads 112a, the to-be-removed portion A1 of the carrier 111, the first to-be-removed portion B1 of the adhesive 113 and the second to-be-removed portion C1 of the heat spreader 114 will not be removed. Only the punch-pressing elements 220 of the die device 200 are used to press the carrier 111, the adhesive 113 and the heat spreader 114 of the tape 100 in the cutting and/or pressing process to generate the separation protrusions C4 protruding from the heat dissipation surface 114a of the heat spreader 114. Preferably, the first restriction protrusions B4 corresponding to the restriction recesses C5 are also formed on the adhesive 113 in the cutting and/or pressing process, and more preferably, the restriction protrusions A4 inserted into the first reserve portion B2 of the adhesive 113 are formed on the carrier 111 in the cutting and/or pressing process.

With reference to FIGS. 6 to 8, after the cutting and/or pressing process, the tape 100 is rolled on a roll (not shown) and a protection tape 500 is provided to separate the rolled and stacked tape 100. The separation protrusions C4 on the tape 100 contact the protection tape 500 located under the tape 100 to prevent the adhesive 113 from being squeezed out. The protection tape 500 and the tape 100 are protected from contamination of the adhesive 113. Additionally, a plurality of protrusions (not shown) may be provided on the protection tape 500 to contact the substrate unit 110 and avoid the protection tap 500 from pressing the hollow portion 110a of the substrate unit 110 or the chip 300.

While this invention has been particularly illustrated and described in detail with respect to the preferred embodiments thereof, it will be clearly understood by those skilled in the art that is not limited to the specific features shown and described and various modified and changes in form and details may be made without departing from the scope of the claims.

1. A tape comprising a plurality of substrate units, each of the plurality of substrate units comprising:
a carrier;
a circuit layer located on the carrier;
an adhesive; and
a heat spreader attached onto the carrier by the adhesive and including a plurality of separation protrusions, the plurality of separation protrusions protrude from a heat dissipation surface of the heat spreader.

2. The tape in accordance with claim 1, wherein the carrier includes an opening and a reserve portion located outside the opening, the adhesive includes a first opening and a first reserve portion located outside the first opening, the heat spreader further includes a second opening and a second reserve portion located outside the second opening, the opening of the carrier, the first opening of the adhesive and the second opening of the heat spreader are a hollow portion of each of the plurality of substrate units, the plurality of separation protrusions are located on the second reserve portion and located outside the second opening of the heat spreader.

3. The tape in accordance with claim 2, wherein the adhesive further includes a plurality of first restriction protrusions, each of the plurality of first restriction protrusions is located in a restriction recess of each of the plurality of separation protrusions.

4. The tape in accordance with claim 3, wherein the carrier further includes a plurality of restriction protrusions which are inserted into the first reserve portion of the adhesive.

5. The tape in accordance with claim 1, wherein the adhesive includes a plurality of first restriction protrusions, each of the plurality of first restriction protrusions is located in a restriction recess of each of the plurality of separation protrusions.

6. The tape in accordance with claim 5, wherein the carrier includes a plurality of restriction protrusions which are inserted into the adhesive.
